(19) United States
(12) Patent Application Publication
(10) Pub. No.: US 2016/0249494 A1
(43) Pub. Date: Aug. 25, 2016

(54) Voltage dividing shielded door seal

(71) Applicant: David Evan Merewether, Albuquerque, NM (US)

(72) Inventor: David Evan Merewether, SR., Albuquerque, NM (US)

(21) Appl. No.: 15/057,499

(22) Filed: Mar. 1, 2016

(51) Int. Cl. H05K 9/00; H05K 5/02; H05K 5/03

(52) U.S. Cl. CPC H05K 9/0016; H05K 5/03; H05K 5/0247

(57) ABSTRACT

A door seal is provided to be used in the construction of a door for a shielded enclosure to assure that high and low frequency elecromagnetic fields do not penetrate the shielded enclosure. The “voltage dividing door seal” of U.S. Pat. No. 4,677,231 is improved by reconfiguring the seal to allow the addition of one or more spring finger rows. This provides a lower impedance seal and less voltage drop across the seal at lower frequencies and consequently, better shielding effectiveness.

### REFERENCES CITED

### U.S. Patent Documents

| | | |
|---|---|---|
| 3,589,070 | June 1971 | Hansen |
| 4,069,618 | January 1978 | Geiss |
| 4,677,251 | June 1987 | Merewether |
| 5,017,736 | May 1991 | Yarger et al. |
| 5,569,878 | October 1996 | Zielinski |
| 5,736,671 | April 1998 | Perala |
| 5,786,547 | July 1998 | Zielinski |
| 7,117,640 B2 | October 2006 | Hurzeler |

### BACKGROUND

Sensitive electronic equipment must be protected from interference or damage by harmful electromagnetic radiation from nearby radio or TV transmitters, radar, nearby lightning strokes and the electromagnetic pulse from a nuclear burst. To provide this protection the equipment is housed in a shielded room (or Faraday cage), an enclosure with continuous metallic walls, floor and ceiling.

The best enclosures are formed from continuously welded metal sheets. When the frequency is high enough that the metal sheets are several skin depths thick, the interior fields are entirely due to leakage at penetrations: air duct filters, power filters, signal line filters, data filters and doors. At low frequencies the magnetic shielding is due to the currents induced in the shield to cancel out the incident field and so the interior fields are related to the inductance of the current path around the inside of the enclosure and the resistance of the metal sheets. It is to be noted that the magnetic shielding effectiveness will naturally decrease with frequency.

As Faraday noted, static electric fields are completely eliminated in the enclosure because charge is redistributed to cancel them out, but the earth's magnetic field is still observable inside the enclosure as there is no canceling direct current included in the shield.

It is evident that the interior fields due to door leakage are determined by the voltage across the door seal on the inside surface of the door panel. All door seal designs seek to reduce that interior voltage.

The simplest seal is a braided wire gasket attached to the outer edge of the door panel to make contact with the door jamb. The edge of the door and the door jamb must both be bare metal, usually solder tinned steel. The problem with this design is primarily that the gasket eventually takes a set leaving gaps in the seal. Secondarily the metallic contact surfaces corrode with time increasing the contact resistance of the gasket.

The prior art seal described in U.S. Pat. No. 3,589,070 issued to Hansen employs a knife edge on the door panel (or the frame) that slides into a channel compressing beryllium copper or phosphor bronze spring fingers on each side of the knife edge. This design reduces the corrosion problem because the spring fingers scrub the oxidization from the contact area. This seal provides very effective shielding at most frequencies but suffers at very high frequencies due to the inductance of the tines of the spring fingers and the small gaps between them.

The knife edge design is incorporated into many subsequent seal designs. The prior art seal described in U.S. Pat. No. 4,069,618 issued to Geiss incorporates the knife edge seal but adds a woven wire gasket placed in the bottom of the spring finger channel. This provides another path for current in parallel with the two rows of spring fingers at low frequencies and attenuation through the gasket at high frequencies. The problems with this design are that it has the same shortcomings as the gasket seal—the gasket takes a set after continued use and there is a loss of effectiveness due to corrosion of the contact surfaces.

The prior Art of U.S. Pat. No. 4,677,251 issued to Merewether utilizes a knife edge seal but introduces a high frequency impedance between the two rows of spring fingers. This is achieved by placing a small gap in one of the contact surfaces of the spring finger channel. Behind this gap is a cavity filled with a lossy dielectric material.

When an unwanted high frequency electromagnetic field is impressed on the outside of the door much of that field is reflected by the low impedance of the first set of spring fingers. The leakage current that passes the first set of spring fingers must pass through the gap in the contact surface before reaching the interior row of spring fingers. The voltage drop across that gap is in series with the inside row of spring fingers. This results in a reduction in the voltage across the inside row of spring fingers. This voltage dividing action is very effective at high frequencies resulting in interior voltage reductions of 10 to 100 times better than results obtained with the knife edge alone.

Moderately low frequency currents must also cross that gap. In addition to the high resistance path through the lossy dielectric, there is also the DC path through connections between the inner and outer shield surfaces of the door panel. In drawings this path is denoted as a continuous metal surface, but in most door designs there are only the connections due to interior structural elements and penetrating bolts for hinges and latches. The resistance of this path is still very small but not negligible compared to the contact resistance of the interior row of spring fingers. Consequently the voltage dividing action is still present even at low frequencies.

### SUMMARY OF THE INVENTION

The present invention is directed at improving the magnetic shielding effectiveness of the “voltage dividing door seal” of U.S. Pat. No. 4,677,251 at low frequencies by providing one or more rows of spring fingers in parallel with the outside row of spring fingers to reduce the DC resistance of the seal. The voltage dividing action expected is still present, so the shielding effectiveness is larger than that provided by a knife edge seal alone.

### BRIEF DESCRIPTION OF THE DRAWINGS

FIG. 1 shows the configuration of the typical shield room door assembly as used in a high quality shielded enclosure.

FIG. 2 is a cutaway view of one embodiment of the prior art door seal of U.S. Pat. No. 4,677,251 for comparison proposes. It shows the relationship of the knife edge and receiver members.

FIG. 3 is a similar cutaway view of one embodiment of the present invention. This drawing can be directly compared to FIG. 2.

FIG. 4 is the equivalent circuit of the present invention as shown in FIG. 3.

FIG. 5 is a cutaway view of one embodiment of the present invention as a seal for the astragal of a shielded double door.

FIGS. 6 and 7 are cutaway views of the present invention where more than one knife edge/receiver combination is used to decrease the low frequency resistance even further for better shielding effectiveness at low frequencies.

### DETAILED DESCRIPTION OF THE DRAWINGS

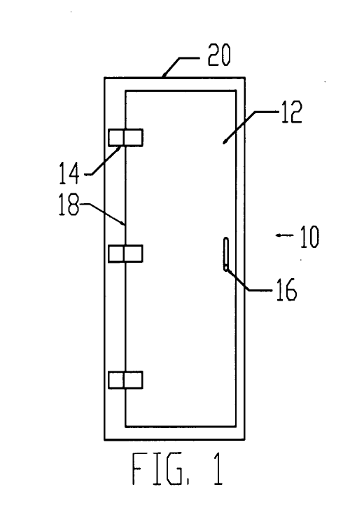

FIG. 1 shows the configuration of the typical shield room door assembly 10. It is to be noted that the shield door frame 20 includes the door threshold since a door seal must be provided all around the periphery of the door panel 12. The frame is often constructed of thick tubular steel welded together and capped to assure that there is no path into the enclosure through the door frame. The door panel should provide the same shielding protection as the walls. It is usually two layers thick so each layer can be thinner than the wall sheets. The door core can be a wood core or a filled metal frame. The hinges 14 must be strong enough to support the weight of the door vertically and strong enough to resist the outward pressure of the door seal upon closure. The number and placement of the hinges depends on the size of the door. The closer 16 is more complicated than a door knob, as it takes considerable force to engage the door seal. The door seal 18 must reflect or absorb the incident energy at high frequencies. At low frequencies 18 must provide a low impedance path for current between the door panel 12 and the frame 20.

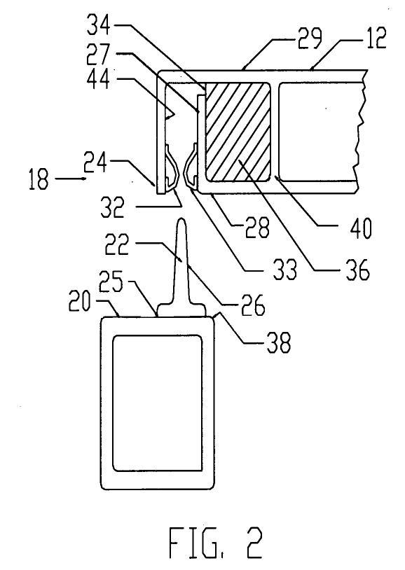

FIG. 2 shows the cut away view 18 of one embodiment of the prior art of U.S. Pat. No. 4,677,251 for comparison purposes.

The knife edge 22 is usually an extrusion of a brass or bronze alloy because extrusions of these materials have less corrosion than steel or copper, and these materials have a low contact resistance with the beryllium copper or phosphor bronze spring finger rows 32 and 33. The knife edge 22 is riveted to the frame 20 but silver soldered in place to eliminate leakage under the knife edge between points 25 and 38. The contact surfaces 44 and 27 are usually brass or bronze extrusions as well, silver soldered to the panel sheets 28 and 29. When the door is closed the outside row of finger stock 32 is compressed by the outside surface of the knife edge 22 and the inside surface 44 of the outside panel 29. The inside row of spring fingers 33 is compressed by the inside surface 26 of the knife edge 22.

When an unwanted electromagnetic field is impressed on the outside of the door a voltage is impressed across the outside gap 24 and 25. That voltage is reduced significantly by the low impedance of the first row of spring fingers 32. That reduced voltage travels over the top of the knife edge 22 to be impressed between surfaces 26 and 27.

The gap 34 in the contact surface 27 allows communication with the cavity filled with a lossy dielectric material 36. As the frequency is increased the losses in the cavity increase the impedance across the gap 34, reducing the voltage across the interior row of spring fingers 33 thereby reducing the voltage across the interior gap between points 38 and 28.

In most door constructions there is no continuous metal barrier 40 at the back of this cavity. The DC path for current flow between the inside and outside surfaces of the door panel is often determined by the number and location of structural reinforcements, hinge bolts and latch bolts.

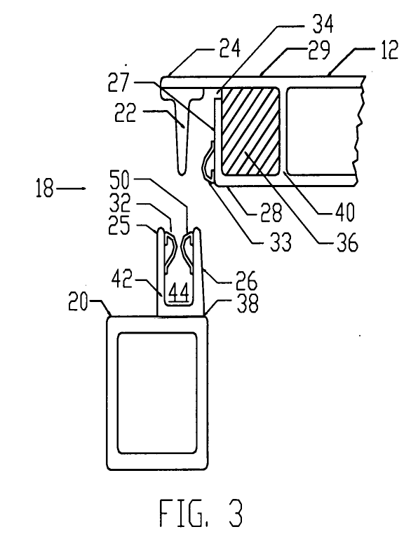

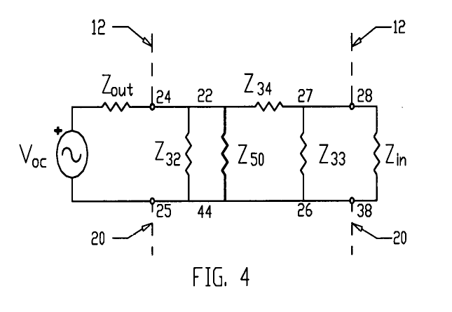

FIG. 3 shows the cut away view of one embodiment of the present invention door seal 18. Here and in all subsequent drawings we have used the same identifying number for the same element of the seal so that a direct comparison with FIG. 2 and FIG. 4 is possible. In this embodiment the knife edge 22 is mounted on the inside surface of the outside sheet 29 of the door panel 12 and is pressed into another brass or bronze extruded channel 42 upon closure. The inside edge 26 of the channel 42 is fabricated with the same slope as the knife edge to compress the inside spring finger row 33. At low frequencies the extra row of spring fingers 50 is in parallel with the outside row of spring fingers 32.

This reduces the low frequency impedance of the present invention to be less than that of prior art shown in FIG. 2, thus increasing the shielding effectiveness of the seal at low frequencies without reducing the increase in the shielding effectiveness due to the voltage dividing effect.

FIG. 4 shows the equivalent circuit of the present invention of FIG. 3. Because we used the same ID number in both FIG. 2 and FIG. 3, this is also the equivalent circuit for the prior art of FIG. 2 except for the reversal of the voltage node notation 22 and 44 since in the present invention the knife edge is mounted on the door panel 12 and not the frame 20. The open circuit voltage V_{oc} is that voltage that would be impressed by the electromagnetic field across the door seal between points 24 and 25 if the seal were a completely open circuit. The outside impedance Zₒᵤₜ is that impedance that would be observed by a voltage source impressed between points 24 and 25 with a completely open door seal. This is not the free space impedance of 377 ohms but it is a relatively high impedance. The inside impedance Zᵢₙ is the impedance seen by a voltage applied across the inside gap 38 to 28 when the door seal is a completely open circuit. This impedance may be close to the outside impedance in a large enclosure at high frequencies. At low frequencies, it is the resistance and inductance of the current path around the inside of the enclosure that control this impedance. Zᵢₙ can be quite small for a small enclosure. This makes it more difficult to obtain high levels of magnetic shielding and is the principle motivation for the present invention. The impedance observed across the gap Z_{gap} in surface 27 is between spring finger rows 33 and 50. The sloped inside surface of item 42 compresses the inside spring finger row 33 and provides the grounding contact surface 26. The first row of spring fingers 32 would have a low impedance Z₃₂; A one foot length of compressed spring fingers would have a contact resistance of a few milliohms. Two rows 32 and 50 as supplied in the present invention would have half the impedance of one row. While the present invention is intended to increase the shielding effectiveness of the seal at low frequencies, the present invention improves the shielding effectiveness of the prior art at all frequencies.

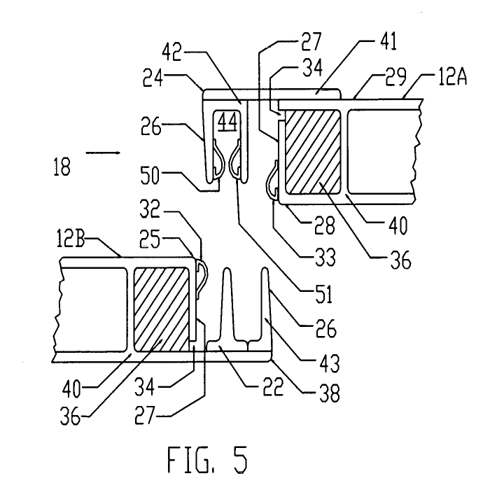

FIG. 5 shows one embodiment of the present invention applied to the astragal of a shielded double door. Here again we retained the same ID numbers used in the prior drawings. It is to be noted that there are now two of the lossy dielectric filled cavities 36 and two voltage dividing gaps 34. The first gap is between the outside row of finger stock 32 and the added spring finger rows 50 and 51.

The presence of this second cavity/gap 36/34 increases the shielding effectiveness at all frequencies. An extrusion 43 is used to compress the inside row of finger stock 33. This seal could also be applied to a door frame/door panel seal.

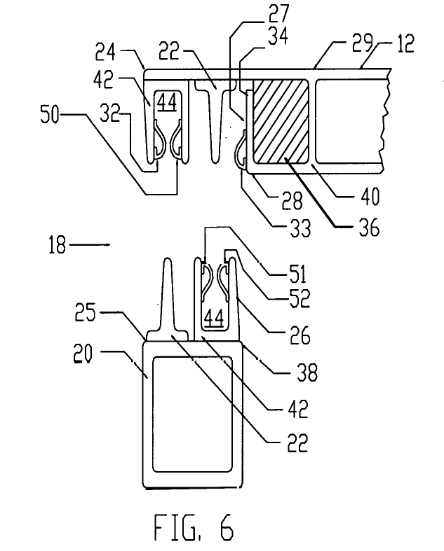

FIG. 6 shows a configuration where both a knife edge extrusion 22 and a channel extrusion 42 are applied to the frame 20 and to the inside surface of the outside sheet 29 of the door panel 12. The outside knife edge 22 on the frame 20 enters the extruded channel 42 mounted on the outside edge of the door panel 18. This channel contains the outside row of spring fingers 32 and one of the added rows of spring fingers 50. The inside knife edge 22 on the door panel enters the channel 42 on the frame which contains two added optional spring finger rows 51 and 52, The frame mounted extrusion 42 compresses the inside row of spring fingers 33 between surface 26 and surface 27. In this configuration either 1, 2 or 3 extra rows of spring fingers 50, 51 and 52 can be used to reduce the low frequency seal resistance.

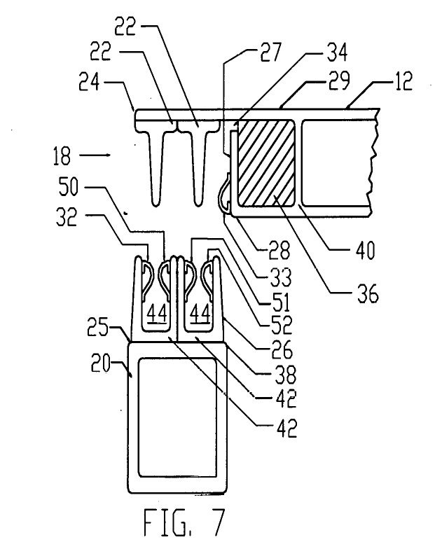

FIG. 7 shows a configuration where two of the knife edge extrusions 22 are applied to the inside surface of she outside sheet 29 of the door panel 12 and two receiver channels 42 are applied to the door frame 20. In this configuration three rows of finger stock 50, 51 and 52 could be used to lower the seal resistance at low frequencies. Comparing FIG. 6 and FIG. 7 reveals that only the location of the inside knife edge 22 and receiving channel 42 are critical to the design.

1. An electromagnetic shielded door seal utilized with a shielded enclosure adapted for use between a door and a door frame, said door seal comprising:
First closure seal member is a metallic channel attached to the door frame.
This channel is fitted with metallic spring finger rows on both inside surfaces of the channel. The outside surface of the inside leg of that channel is sloped to compress spring fingers when the door is closed.
Second enclosure seal member is a metallic knife edge attached to the inside surface of the outside sheet of the door panel. This member is positioned to form a slot between the knife edge and the vertical surface connected to the inside surface of the door panel.
The vertical surface connected to the inside sheet of the door panel is separated from the outside surface of the door panel by an intentional gap. This surface is also fitted with a spring finger row below the gap that is compressed by the sloped surface on the first closure seal member.
Behind said gap is a cavity within the door panel filled with an energy absorbing lossy dielectric material.

2. An electromagnetic shielded door seal door seal in accordance with claim 1 adapted for use at the astragal of a shielded double door assembly with:
First closure seal member is a metallic channel attached to the inside surface of the outside sheet of the principle door panel. This channel is fitted with metallic spring finger rows on both inside surfaces of the channel. This member is positioned to form a slot between the inside surface of the channel and the vertical surface connected to the inside sheet of the principle door panel. The outside surface of this channel is sloped to compress the outside row of spring fingers on the vertical surface attached to the outside sheet of the secondary door panel.
Second enclosure seal member is a metallic knife edge attached to the door frame that is aligned to engage the first closure seal member.
Third enclosure seal member is a half knife edge that compresses the inside row of finger stock on the vertical surface connected to the inside sheet of the principle door panel.
The vertical surface attached to the outside sheet of the secondary door panel is separated from the inside surface of the secondary door panel by an intentional gap. This surface is also fitted with a spring finger row above the gap.
Behind said gap is a cavity within the secondary door panel filled with an energy absorbing lossy dielectric material.
The vertical surface attached to the inside sheet of the principle door panel is separated from the inside surface of the outside sheet of the principle door panel by an intentional gap. This surface is also fitted with a spring finger row below the gap.
Behind said gap is a cavity within the door panel filled with an energy absorbing lossy dielectric material.

3. An electromagnetic shielded door seal in accordance with claim 1 with:
One knife edge and one channel attached to the inside surface of the outside sheet of the door panel.
One knife edge and one channel is attached to the door frame.
Each channel is fitted with metallic spring fingers rows on the inside surface of the channel.
The channel on the door frame is located closest to the inside so as to compress a spring finger row located on the bottom of the vertical surface attached to the inside sheet of the door panel.
The vertical surface attached to the inside sheet of the door panel is separated from the inside surface of the outside sheet of the door panel by an intentional gap.
Behind said gap is a cavity within the door panel filled with an energy absorbing lossy dielectric material.

4. An electromagnetic shielded door seal in accordance with claim 1 with:
Two metallic channels are attached to the door frame. Each channel is fitted with metallic spring finger rows on the inside surfaces of the channel.
Two metallic knife edge extrusions are attached to the inside surface of the outside sheet of the door panel.
The vertical surface connected to the inside surface of the door panel is separated from the inside surface of outside sheet of the door panel by an intentional gap. This surface is also fitted with a spring finger row below the gap.
This spring finger row is compressed by the sloped surface on the inside leg of the inside channel mounted on the door frame.
Behind said gap is a cavity within the door panel filled with an energy absorbing lossy dielectric material
